(19) United States
(12) Patent Application Publication
(10) Pub. No.: US 2026/0186021 A1
(43) Pub. Date: Jul. 2, 2026

(54) VERTICAL MEMS PROBE HAVING TETHERING STRUCTURE AND MANUFACTURING METHOD THEREOF

(71) Applicant: WithMEMS Co., Ltd., Hwaseong-si (KR)

(72) Inventors: Hwang-sub KOO, Hwaseong-si (KR); Seok Hwan YOO, Hwaseong-si (KR); Jong-Uk BU, Hwaseong-si (KR); Sanghyeop LEE, Hwaseong-si (KR); Ho Sub BANG, Hwaseong-si (KR); Jaewoo CHA, Hwaseong-si (KR)

(73) Assignee: WithMEMS Co., Ltd., Hwaseong-si (KR)

(21) Appl. No.: 19/301,012

(22) Filed: Aug. 15, 2025

(30) Foreign Application Priority Data
Dec. 30, 2024 (KR) 10-2024-0200757
Mar. 31, 2025 (KR) 10-2025-0041371

(51) Int. Cl. G01R 1/067; B81B 3/00; B81C 1/00

(52) U.S. Cl. CPC G01R 1/06727; B81B 3/0021; B81C 1/0015; G01R 1/06744; B81B 2201/0292; B81B 2203/0118; B81C 2203/0136

(57) ABSTRACT

Proposed are a vertical MEMS probe having a tethering structure and a manufacturing method thereof. The probe includes a pin including a contact portion that contacts at least one of two ends thereof and an elastic portion that withstands a contact load applied to the contact portion by an elastic restoring force between the two ends, a housing having a penetration portion that exposes the contact portion to an outside, and configured to cover the elastic portion, and a tether configured to connect the contact portion and the housing or the elastic portion and the housing, wherein a first connection portion between the contact portion or the elastic portion and the housing, a second connection portion between the housing and the tether, or the tether may be separated.

### CROSS REFERENCE TO RELATED APPLICATION

The present application claims the benefit of priority to Korean Patent Application Nos. 10-2024-0200757 filed on Dec. 30, 2024 and 10-2025-0041371 filed on Mar. 31, 2025, the entire contents of which are incorporated herein by reference for all purposes.

### BACKGROUND

### Technical Field

The present disclosure relates to a probe for microelectrode circuit inspection and, more particularly, to a vertical MEMS probe having a tethering structure and a manufacturing method thereof.

### Description of the Related Art

A probe for microelectrode circuit inspection is a probe that can be used in a probe card or test socket for inspection and testing of an object by coming into contact with the object, and consists of a contact portion, an elastic portion that withstands the contact load applied to the contact portion with an elastic restoring force, and a housing that covers the elastic portion.

The probe for microelectrode circuit inspection can be manufactured using the micro-electro-mechanical systems (MEMS) process. The process of manufacturing the probe for microelectrode circuit inspection using the MEMS process involves applying photoresist to the surface of a conductive substrate and then patterning the photoresist. After that, a metal material is deposited into the opening via electroplating using the photoresist as a mold, and the photoresist and conductive substrate are removed to obtain a probe for microelectrode circuit inspection. In this case, a plurality of metal materials forming a pin including the contact portion and the elastic portion and the housing covering the pin are laminated in the upper and lower layers, while a sacrificial layer acting as a spacer is formed between the metal materials, and the probe for microelectrode circuit inspection is created by removing the sacrificial layer so that the pin and the housing are separated. However, when the last sacrificial layer is removed, the pin may bend due to residual stress, etc.

### Document of Related Art

(Patent Document 1) Korean Patent No. 10-2018784

### SUMMARY

Accordingly, the present disclosure has been made keeping in mind the above problems occurring in the related art, and the present disclosure is intended to provide a vertical MEMS probe having a tethering structure that can prevent the bending of a probe pin that occurs when removing a sacrificial layer, and a manufacturing method of the probe.

The objectives of the present disclosure are not limited to the one mentioned above, and other objectives not mentioned will be clearly understood by those skilled in the art from the description below.

In order to achieve the above objective, according to an aspect of the present disclosure, there is provided a vertical MEMS probe having a tethering structure, the probe including: a pin including a contact portion that contacts at least one of two ends thereof and an elastic portion that withstands a contact load applied to the contact portion by an elastic restoring force between the two ends; a h housing having a penetration portion that exposes the contact portion to outside, and configured to cover the elastic portion; and a tether configured to connect the contact portion and the housing or the elastic portion and the housing, wherein a first connection portion between the contact portion or the elastic portion and the housing, a second connection portion between the housing and the tether, or the tether may be separated.

The first connection portion, the second connection portion, or the tether may be destroyed and separated by a mechanical external force during use of the vertical MEMS probe.

Fracture toughness of the first connection portion, the second connection portion, or the tether may be greater than a bending moment produced by residual stress of the contact portion and the elastic portion.

In a process where the first connection portion, the second connection portion, or the tether is destroyed by the mechanical external force, mechanical damage or plastic deformation of the contact portion or the elastic portion may not occur.

The tether may include a notch.

The first connection portion, the second connection portion, or the tether may be separated using chemical etching.

The chemical etching may include galvanic corrosion.

A detether portion may be included between the contact portion or the elastic portion and the tether, or between the housing and the tether, wherein the detether portion is removed by the chemical etching.

The tether may be divided into a first tether and a second tether, and a detether portion may be further included between the first tether and the second tether, wherein the detether portion may be removed by the chemical etching.

When the chemical etching includes galvanic corrosion, a corrosion potential of the detether portion may be lower than that of the contact portion and the elastic portion.

The housing may be divided into an upper housing, a side wall housing, and a lower housing, and a current-conducting plating layer that acts as a current-conducting path may be formed between plating layers forming any one of the upper housing, the side wall housing, and the lower housing or for a specific plating layer.

A short circuit with the current-conducting plating layer may be created through an overall post-processing gold (Au) plating on the housing.

In order to achieve the above objective, according to another aspect of the present disclosure, there is provided a manufacturing method of a vertical MEMS probe having a tethering structure, the method including: forming a tether that connects a contact portion and a housing or connects an elastic portion and the housing in a process of laminating a plurality of metal materials forming a pin including the contact portion that contacts at least one of two ends of the pin and the elastic portion that withstands a contact load applied to the contact portion by an elastic restoring force between the two ends and the housing having a penetration portion that exposes the contact portion to outside, and configured to cover the elastic portion, in a manufacturing process of the probe having elasticity for examining electrical characteristics of an electrical or electronic device.

The method may include separating a first connection portion between the contact portion or the elastic portion and the housing, a second connection portion between the housing and the tether, or the tether.

The first connection portion, the second connection portion, or the tether may be destroyed and separated by a mechanical external force during use of the vertical MEMS probe.

The method may include making fracture toughness of the first connection portion or the second connection portion to be greater than a bending moment produced by residual stress of the contact portion and the elastic portion.

The method may include providing a notch in the tether.

The method may include separating the first connection portion, the second connection portion, or the tether using chemical etching including galvanic corrosion.

The method may include providing a galvanic sacrificial layer to which the galvanic corrosion is applied with a metal material that is more electrochemically reactive than a metal material applied to the contact portion and the elastic portion.

The method may include forming a detether portion between the contact portion or the elastic portion and the tether, or between the housing and the tether.

The method may include removing the detether portion using the chemical etching of the galvanic corrosion.

The method may include dividing the tether into a first tether and a second tether, and further providing a detether portion between the first tether and the second tether.

The method may include removing the detether portion using the chemical etching of the galvanic corrosion.

The method may include dividing the housing into an upper housing, a side wall housing, and a lower housing, and forming a current-conducting plating layer that acts as a current-conducting path between plating layers forming any one of the upper housing, the side wall housing, and the lower housing or for a specific plating layer.

The method may include creating a short circuit with the current-conducting plating layer through an overall post-processing gold (Au), silver (Ag), or platinum (Pt) plating on the housing.

The method may include forming a thickness of the elastic portion close to the contact portion that comes into contact with a test object to be greater than that of the elastic portion close to an auxiliary contact portion that comes into contact with a circuit board of a probe card.

Therefore, the present disclosure can prevent bending of a probe pin that occurs when removing a sacrificial layer.

Furthermore, the present disclosure can provide the probe pin in a fine pitch type.

The effects of the present disclosure are not limited to the ones mentioned above, and other effects not mentioned will be clearly understood by those skilled in the art from the description of the claims.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a schematic view showing a vertical MEMS probe according to an embodiment of the present disclosure;

FIG. 2 is a schematic view showing a vertical MEMS probe according to another embodiment of the present disclosure;

FIG. 3 is a cross-sectional view of a probe corresponding to a first process in the manufacturing process for the vertical MEMS probe of FIG. 1;

FIG. 4 is a cross-sectional view of a probe showing the bent state of a probe pin of FIG. 3;

(a) and (b) of FIG. 5 are conceptual views showing the bent state of the probe pin of FIG. 4 in more detail;

FIG. 6 is a cross-sectional view of a probe corresponding to a second process in the manufacturing process for the vertical MEMS probe of FIG. 1;

FIG. 7 is a cross-sectional view showing a more specific example of a tether of FIG. 6;

FIG. 8 is a cross-sectional view showing another more specific example of the tether of FIG. 6;

FIG. 9 is an example view showing a notch formed in a part of the tether of FIG. 6;

(a) to (c) of FIG. 10 are conceptual views showing the bending moment applied to the notch of FIG. 9;

FIG. 11 is a cross-sectional view showing still another more specific example of the tether of FIG. 6;

FIG. 12 is an example view showing a partial cross-section of the probe of FIG. 9;

(a) and (b) of FIG. 13 are example views showing a current-conducting plating layer provided in a housing of FIG. 12 as an example;

FIG. 14 is an example view showing other examples of the current-conducting plating layer shown in 13A;

(a) to (c) of FIG. 15 are example views showing another example of the current-conducting plating layer provided in the housing of FIG. 12; and

FIG. 16 is a flow chart showing a manufacturing method of a vertical MEMS probe according to an embodiment of the present disclosure.

### DETAILED DESCRIPTION

Hereinafter, embodiments will be described in detail with reference to the attached drawings. However, the scope of the patent application is not limited or restricted by these embodiments. The same reference numerals presented in each drawing represent the same components.

The embodiments described below may be modified in various ways. The embodiments described below are not intended to be limiting in terms of the aspects, and should be understood to include all modifications, equivalents, or alternatives to them.

The terms first or second may be used to describe various components, but these terms should be understood only for the purpose of distinguishing one component from another. For example, a first component may be referred to as a second component, and similarly, a second component may also be referred to as a first component.

The terms used in the embodiments are used only to describe specific embodiments and are not intended to limit the embodiments. Singular expressions include plural expressions unless the context clearly indicates otherwise. In this specification, each of the phrases “A or B”, “at least one of A and B”, “at least one of A or B”, “A, B or C”, “at least one of A, B and C”, and “at least one of A, B, or C” can include any one of the items listed together in that phrase, or all possible combinations thereof. In this specification, it should be understood that terms such as “comprise (include)” or “have” are intended to specify the presence of a feature, number, step, operation, component, part or combination thereof described in the specification, but do not exclude in advance the possibility of the presence or addition of one or more other features, numbers, steps, operations, components, parts or combinations thereof.

Unless otherwise defined, all terms used herein, including technical or scientific terms, have the same meaning as commonly understood by one of ordinary skill in the art to which the embodiments belong. Terms defined in commonly used as having a meaning dictionaries should be interpreted consistent with their meaning in the context of the relevant art, and will not be interpreted in an idealized or overly formal sense unless expressly defined in this application.

In addition, when explaining with reference to the attached drawings, identical components are given the same reference numerals regardless of the drawing numbers, and redundant descriptions thereof are omitted. In describing an embodiment, if it is judged that a detailed description of a related known technology may unnecessarily obscure the gist of the embodiment, the detailed description is omitted.

A vertical MEMS probe having a tethering structure and a manufacturing method thereof of the present disclosure are configured to prevent bending of a probe pin that occurs when a sacrificial layer is removed in a manufacturing process of a probe pin having elasticity for examining electrical characteristics of an electrical or electronic device, and provide the probe pin in a fine pitch type.

Hereinafter, embodiments of the present disclosure will be described in detail with reference to the attached drawings.

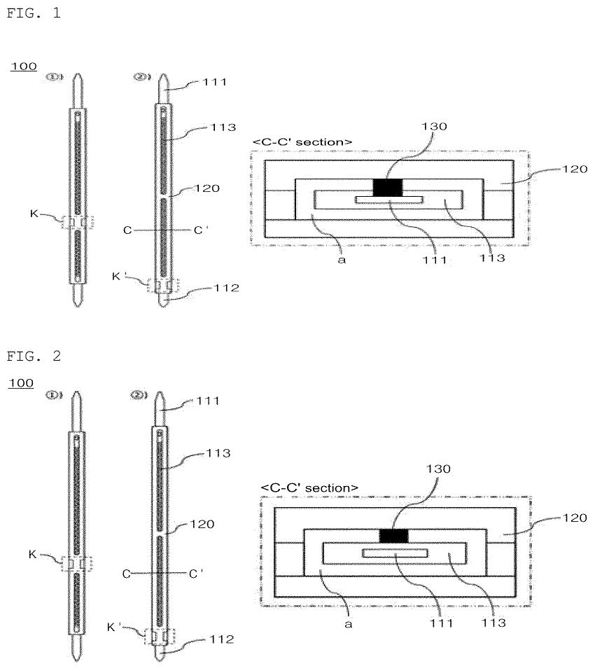

FIG. 1 is a schematic view showing a vertical MEMS probe according to an embodiment of the present disclosure.

FIG. 1 shows a vertical MEMS probe 100 having two types of tethering structures. A first type of vertical MEMS probe 100 is illustrated in part \textcircled{1} of FIG. 1, and a second type of vertical MEMS probe 100 is illustrated in part \textcircled{2} of FIG. 1.

The first type of vertical MEMS probe 100 is based on two spring structures and includes a tethering structure between pins and a tethering structure within a pin.

The tethering structure between pins is to prevent pins from scattering, tilting, or tangling when separated from a substrate during the final separation of thousands to tens of thousands of pins in the MEMS process, making precise position control and packaging difficult. This ensures that the pins remain aligned on the substrate (wafer) without collapsing after extraction, and makes it easy to handle the pins in batches in the desired shape during subsequent post-processing (packaging, assembly).

Since the first type of vertical MEMS probe 100 has a two-spring structure, the tethering configuration K between the pins is located in the middle as shown in part \textcircled{1} of FIG. 1.

Meanwhile, since the second type of vertical MEMS probe 100 has a single spring structure, the tethering configuration K′ between the pins is located at the bottom as shown in part \textcircled{2} of FIG. 1.

Hereinafter, the tethering structure within the pin will be described in detail using the second type of vertical MEMS probe 100 as an example.

The vertical MEMS probe 100 having a tethering structure includes: a pin 110 including a contact portion 111 that contacts at least one of the two ends thereof and an elastic portion 113 that withstands the contact load applied to the contact portion 111 by the elastic restoring force between the two ends; a housing 120 having a penetration portion a that exposes the contact portion 111 to the outside, and configured to cover the elastic portion 113; and a tether 130 connecting the contact portion 111 and the housing 120 or the elastic portion 113 and the housing 120. A separation of a first connection portion between the contact portion 111 or the elastic portion 113 and the housing 120, a second connection portion between the housing 120 and the tether 130, or the tether 130 is possible.

In this case, the contact portion 111 is a portion that comes into contact with a test object (e.g., wafer, chip, etc.), and on the opposite side of the contact portion 111, an auxiliary contact portion 112 that comes into contact with a circuit board of a probe card is positioned.

As shown on the right side of FIG. 1, the tether 130 is provided with a structure that connects the contact portion 111 and the housing 120, so that the bending of the contact portion 111 due to residual stress applied to the contact portion 111 when removing a sacrificial layer laminated on the penetration portion a may be prevented.

The probe pin 110 manufactured using the MEMS process may bend or deform due to residual stress generated during the manufacturing process. However, the contact portion 111 of the probe pin 110 may be maintained the vertical shape as designed due to the tether 130. In addition, the tether 130 is utilized to prevent the probe pin 110 from moving or bending haphazardly during the process of removing the sacrificial layer, and to continuously maintain the vertical shape that has already been formed.

FIG. 2 is a schematic view showing a vertical MEMS probe according to another embodiment of the present disclosure.

As shown on the right side of FIG. 2, the tether 130 is provided with a structure that connects the elastic portion 113 and the housing 120, so that the bending of the elastic portion 113 due to residual stress applied to the elastic portion 113 when removing the sacrificial layer laminated on the penetration portion a may be prevented.

The tether 130 may be provided with a structure in which all or part of the tether 130 is removed or remains maintained after the sacrificial layer is removed.

That is, after the sacrificial layer is removed, the first connection portion connecting the contact portion 111 or the elastic portion 113 and the housing 120, the second connection portion connecting the housing 120 and the tether 130, or the tether 130 may be destroyed and separated by mechanical external force during use of the vertical MEMS probe 100.

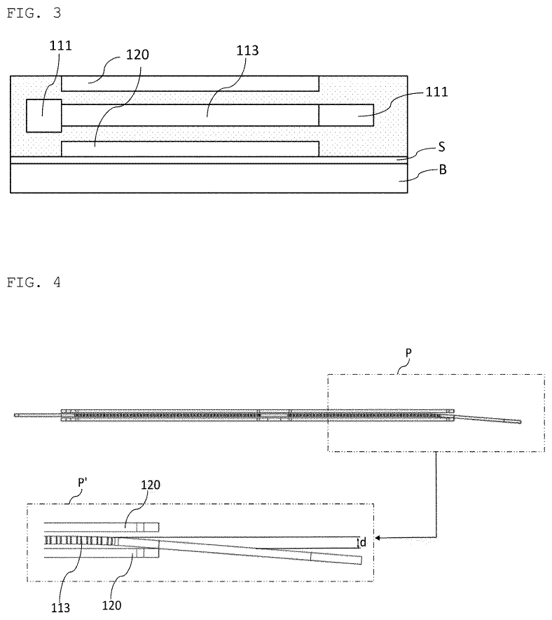

FIG. 3 is a cross-sectional view of a probe corresponding to a first process in the manufacturing process for the vertical MEMS probe of FIG. 1.

As shown in FIG. 3, the manufacturing process for manufacturing a vertical MEMS probe 100 includes a first process of laminating, before forming the probe pin 110 and the housing 120, a sacrificial layer material between these two structures. The sacrificial layer material includes silicon oxide (SiO₂), polymers, metal layers (e.g., aluminum, copper), etc., and after the sacrificial layer is laminated, additional structures such as the housing 120 are laminated.

Afterwards, a process of removing the sacrificial layer is performed, and wet etching or dry etching may be used as a method of removing the sacrificial layer.

In this case, wet etching is a method of selectively dissolving a sacrificial layer using a chemical solution. For a silicon oxide (SiO₂) sacrificial layer, hydrofluoric acid (HF) may be used, for an aluminum (Al) sacrificial layer, an alkaline solution (e.g., NaOH, KOH) may be used, and for a copper (Cu) sacrificial layer, nitric acid (HNO₃) or a sulfuric acid-hydrogen peroxide mixture may be used. Wet etching enables relatively rapid removal of the sacrificial layer, and as the solution spreads, the solution penetrates into every corner of the probe structure and dissolve the sacrificial layer, but there is also a risk that excessive etching may damage the probe structure.

On the other hand, dry etching is a method of removing a sacrificial layer using plasma or a reactive gas, and includes reactive ion etching (RIE) that removes a sacrificial layer using gases such as SF₆ and CF₄, or gas plasma etching that selectively removes silicon using XeF₂ (xenon difluoride). Dry etching allows for enhanced precision and minimizes the risk of damage to the probe structure, but has the disadvantage of a rather long process time.

FIG. 4 is a cross-sectional view of a probe showing the bent state of a probe pin of FIG. 3, and (a) and (b) of FIG. 5 are conceptual views showing the bent state of the probe pin of FIG. 4 in more detail.

As shown in FIG. 4, during the process of removing the sacrificial layer, the elastic portion 113 and the contact portion 111 of the pin 110 may bend or deform due to residual stress, etc., and this can be understood by referring to a cantilever structure with one end thereof fixed.

In the case of the cantilever structure, assuming that the stress is distributed linearly along the thickness and this is denoted by Γ, the deflection value δ(x) at any x position can be calculated using the following Formula 1.

$$δ ( x ) = \frac{{Mx}^{2}}{2 EI} = \frac{Γ}{2 E} {x}^{2} \qquad 〈 Formula 1 〉$$

(where, E: Young's Modulus, M: bending moment, I: moment of inertia, Γ: stress)

In addition, the bending moment can be calculated using the following Formula 2.

$$M = Γ x I \qquad 〈 Formula 2 〉$$

The moment of inertia can be calculated following Formula 3.

$$I = w {t}^{3} / 12 \qquad 〈 Formula 3 〉$$

(where, w: width, t: thickness)

As the length of the beam applied to the cantilever structure increases, the deflection in the longitudinal direction of the beam increases quadratically (proportional to x²), and the moment of inertia and the bending moment increase cubically with respect to the thickness and linearly with respect to the width, and thus the deflection increases cubically as the thickness of the beam decreases, and increases proportionally as the width decreases.

That is, with reference to drawings of (a) and (b) of FIG. 5, as the pitch of the probe pin 110 becomes narrower, the width and thickness of the pin 110 decrease, and accordingly, the moment of inertia and the bending moment in the longitudinal direction of the probe pin 110 increase exponentially.

In particular, the bending moment at the end of the probe pin 110 acts quite significantly (maximum bending occurs, and the difference in the end of the contact portion before and after the bending occurs is a step d), which causes the probe pin 110 to physically contact the housing 120.

The bending moment for the probe pin 110 may occur when the sacrificial layer is removed due to one or more of the following: lattice mismatch between the sacrificial layer and the probe pin structure plating layer during plating, residual stress generated during plating, processing stress generated by external stress during the CMP (chemical mechanical polishing) process performed after plating, and the influence of self-weight.

The direction of bending is determined by whether the stress gradient that affects the occurrence of the bending moment involves tensile stress or compressive stress.

Such a bending moment may cause a problem in that when the sacrificial layer is removed during the manufacturing process of the probe pin 110 and the surface is plated for conductivity and wear resistance, plating bonding occurs and the probe pin 110, including the elastic portion and the contact portion, is joined to the housing 120, or a high electric field is physically generated during the surface plating, thereby causing a thicker plating layer at a specific location on a part compared to other areas.

This causes the probe pin 110 to malfunction, makes it difficult to ensure uniform quality during mass production of the probe pin 110, and causes the elastic portion 113 to buckle due to deformation of the probe pin 110.

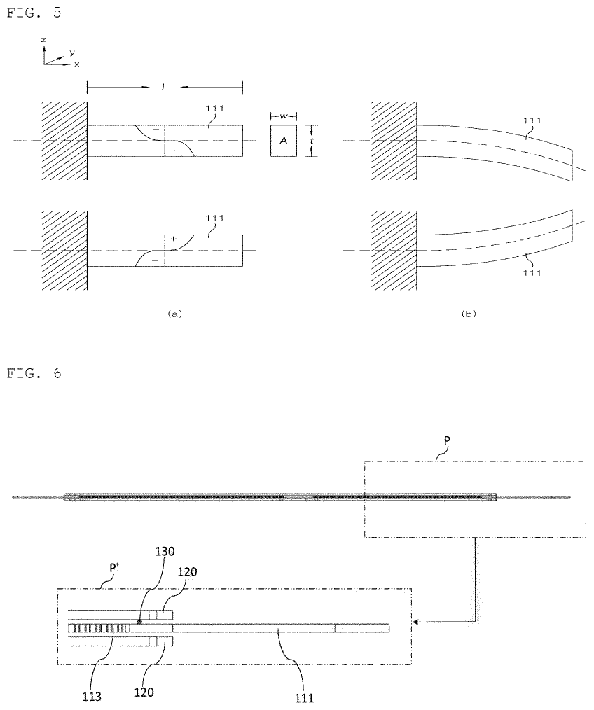

FIG. 6 is a cross-sectional view of a probe corresponding to a second process in the manufacturing process for the vertical MEMS probe of FIG. 1.

As shown in FIG. 6, the vertical MEMS probe 100 of the present disclosure is formed of the tether 130 capable of withstanding the bending of the pin, thereby preventing plating bonding occurring in the sacrificial layer removal process and the plating process, and ensuring a uniform post-plating thickness.

Such a tethering structure may be provided so as to have a physical condition that allows the structure to be easily destroyed by an external force after or before the assembly of the probe pin 110.

The fracture toughness of the first connection portion connecting the contact portion 111 or elastic portion 113 of the pin 110 and the tether 130, or the second connection portion connecting the housing 120 and the tether 130 may be greater than the bending moment produced by the residual stress of the contact portion 111 and the elastic portion 113.

At this time, it is desirable to have a tethering structure in which mechanical damage or plastic deformation of the contact portion 111 or elastic portion 113 does not occur during the process in which the first connection portion, the second connection portion, or the tether 130 is destroyed by a mechanical external force.

The tethering structure is destroyed without causing any damage or deformation to the pin structure after the probe pin 110 is manufactured, and acts as a trigger that allows the elastic portion 113 of the pin 110 to act.

That is, the tethering structure for this may be provided with a material having etch selectivity (e.g., the same material as the housing) with respect to the sacrificial layer, but is not limited thereto. The structure forming the tether 130 may be provided based on a structural design that enables the contact portion 111 and elastic portion 113 of the probe pin 110 to withstand the bending moment produced after the sacrificial layer process, and it is necessary for the structure forming the tether 130 to have a structural feature that does not cause mechanical damage or plastic deformation to the contact portion 111 or elastic portion 113 of the probe pin 110 when a specific mechanical external force for detethering is applied.

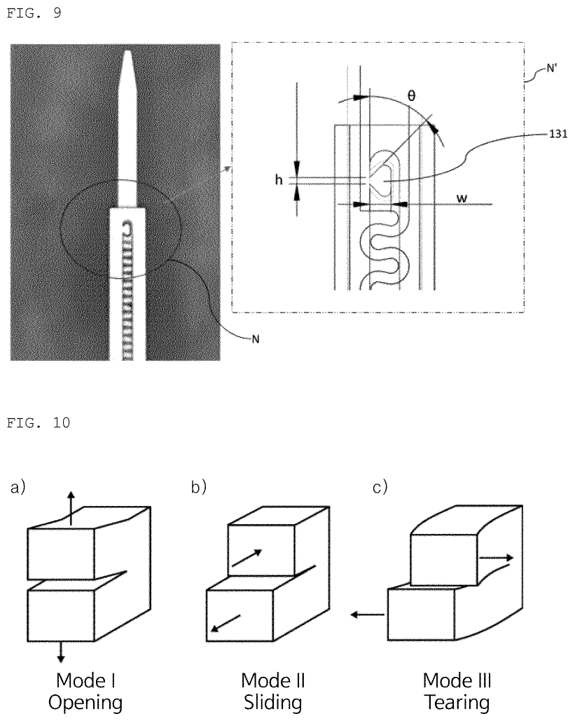

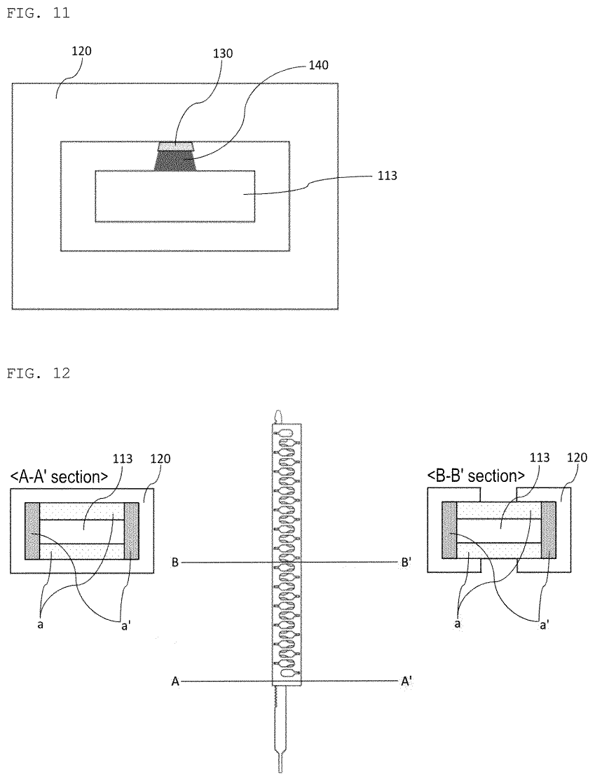

As an example, a tethering structure including a notch in the tether 130 may be provided, and a more detailed description thereof will be provided below in FIG. 9.

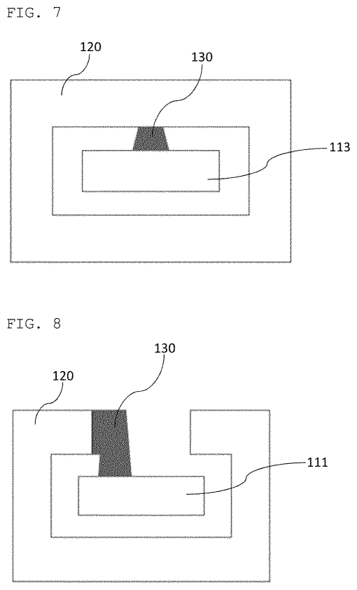

FIG. 7 is a cross-sectional view showing a more specific example of a tether of FIG. 6, and FIG. 8 is a cross-sectional view showing another more specific example of the tether of FIG. 6.

As shown in FIG. 7 or 8, by forming the tether 130 such that the size of the bottom thereof is larger than that of the top thereof in terms of the cross-section, the portion thereof that holds the contact portion 111 or elastic portion 113 of the probe pin 110 in the process of removing the sacrificial layer is further expanded, and by having the structure that supports the expanded portion with the tether 130 connected to the housing 120, the influence of the bending moment applied to the contact portion 111 or elastic portion 113 of the probe pin 110 in the process of removing the sacrificial layer may be minimized.

FIG. 9 is an example view showing a notch formed in a part of the tether of FIG. 6.

As shown in FIG. 9, a tethering structure including a notch N in the tether 130 is exposed on the upper part of the housing 120 to support the contact portion 111 or the elastic portion 113 of the probe pin 110, and the notch N exposed on the upper part of the housing 120 is connected to the side wall of the housing 120 with a predetermined area size, and the lower part of the notch N is provided with a structure that supports the contact portion 111 or the elastic portion 113 of the probe pin 110.

The predetermined area size connected between the notch N and the side wall of the housing 120 may be determined on the basis of the ease of destruction by a mechanical external force and the support force sufficient to prevent deformation of the contact portion 111 or the elastic portion 113 of the probe pin 110 during the removal process of the sacrificial layer.

In addition, in the case of removing the notch N, the mechanical external force transmitted to the contact portion 111 in contact with the test object acts in the direction of the elastic portion 113, so that damage to the contact portion 111 or the elastic portion 113 of the probe pin 110 located below the notch N may be prevented while removing the notch N.

(a) and (c) of FIG. 10 are conceptual views showing the bending moment applied to the notch of FIG. 9.

The shear stress mode applied to the notch N that prevents the deformation of the contact portion 111 or elastic portion 113 of the probe pin 110 during the removal process of the sacrificial layer may be the Tearing mode as shown in (c) of FIG. 10, and may be the Opening mode as shown in (a) of FIG. 10 in the process of removing and destroying the notch N.

The structural design of such a notch N may be provided so that the stress concentration factor K_{IC} of the tethering structure at the position x applied to the probe (100) must be greater than the bending moment of the previously described Formula 2, and may cause destruction without causing plastic deformation of the elastic portion 113 or the contact portion 111 of the probe pin 110.

FIG. 11 is a cross-sectional view showing still another more specific example of the tether of FIG. 6.

The tethering structure may be provided so that the first connection portion connecting the contact portion 111 or elastic portion 113 of the pin 110 and the tether 130, the second connection portion connecting the housing 120 and the tether 130, or the tether 130 may be separated using chemical etching.

The chemical etching described above may include galvanic corrosion, and such galvanic corrosion includes electrochemical etching (ECE), which is a method of applying electric current to a metal surface using an electrode to selectively dissolve a specific area.

Referring to FIG. 11, the vertical MEMS probe 100 may further include a detether portion 140 between the contact portion 111 or the elastic portion 113 and the tether 130, or between the housing 120 and the tether 130, and may further have a structure that allows the detether portion 140 to be removed by chemical etching.

In FIG. 11, a structure having the detether portion 140 between the elastic portion 113 and the tether 130 is shown. After removing the sacrificial layer, the detether portion 140 is removed by chemical etching, thereby preventing bending of the elastic portion 113 during the process of removing the sacrificial layer. Then, the function of the elastic portion 113 within the probe pin 110 is enabled by chemically removing the detether portion 140.

At this time, when the chemical etching includes galvanic corrosion, the corrosion potential of the detether portion 140 is made lower than the corrosion potential of the elastic portion 113, so that only the detether portion 140 is removed while the elastic portion 113 of the probe pin 110 is preserved.

Similarly, in a structure having the detether portion 140 between the contact portion 111 and the tether 130, the corrosion potential of the detether portion 140 is made lower than the corrosion potential of the contact portion 111 for the same reason as described above.

The detether portion 140 may be provided with a structure in which different materials are laminated and plated, and should have etching selectivity so as not to be etched when the sacrificial layer is removed. The detether portion 140 may be made of a metal material that is more electrochemically reactive than the contact portion 111 and elastic portion 113 of the probe pin 110, and the housing 120, and needs to form a galvanic pair with the contact portion 111 and elastic portion 113 of the probe pin 110, and the housing 120.

As an example, when applying Ni alloy to the contact portion 111 and elastic portion 113 of the probe pin 110, and the housing 120, the laminated plating material of the detether portion 140 may be a metal such as Fe, Zn, or Al, but is not limited thereto.

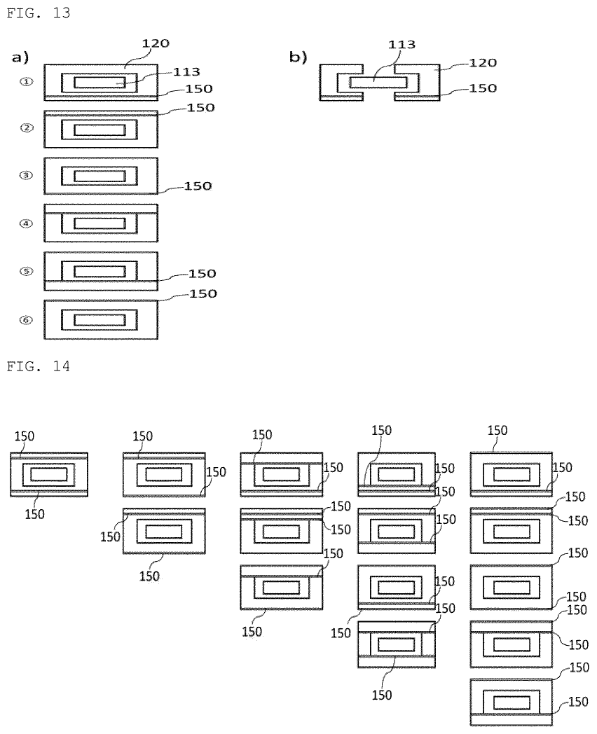

FIG. 12 is an example view showing a partial cross-section of the probe of FIG. 9.

As shown in the A-A′ and B-B′ sections of FIG. 12, in order to improve the probe pin 110 to a fine pitch type, it is necessary to solve the problem of deterioration of electrical characteristics due to the limitation of the thickness of the post-processing plating stemming from the size constraints of the structure constituting the probe pin 110 and the constraints of an X-axis space (a) and an Y-axis space (a′) inside the probe 100.

For example, in a probe (100) having a width (X-axis) of the housing 120 of 50 μm or less, a height (Y-axis) of the housing 120 of 35 μm or less, and a height of the elastic portion 113 of 10 μm or less, if a gap (gap in the X-axis and Y-axis directions) between the elastic portion 113 and the housing 120 is 4 μm or more, plastic deformation of the elastic portion 113 due to buckling may occur during operation of the probe 100. Thus, the gap between the elastic portion 113 and the housing 120 needs to be reduced.

However, if the gap between the elastic portion 113 and the housing 120 is reduced, plating bonding occurs in the surface plating process (e.g., Rh/Au electroplating) for conductivity and wear resistance, resulting a bonding problem between the pin 110 including the elastic portion 113 and the contact portion 111, and the housing 120.

To solve this problem, in the vertical MEMS probe 100 of the present disclosure, the housing 120 may be divided into an upper housing, a side wall housing, and a lower housing, and a current-conducting plating layer 150 that acts as a current-conducting path may be formed between plating layers forming any one of the upper housing, the side wall housing, and the lower housing or for a specific plating layer.

In addition, a short circuit with the current-conducting plating layer 150 may be created through the overall post-processing gold (Au) plating on the housing 120.

The thickness of the current-conducting plating layer 150 (Au, Ag, or Pt electroplating layer) is 0.5 to 5 μm or less, and the thickness of the post-processing plating (Au, Ag, or Pt) is 0.05 to 0.3 μm.

(a) and (b) of FIG. 13 are example views showing a current-conducting plating layer provided in a housing of FIG. 12 as an example.

(a) of FIG. 13 shows the current-conducting plating layer 150 that can correspond to the A-A′ cross-section, and the current-conducting plating layer 150 may be formed on any one part of the upper housing, the side wall housing, and the lower housing. Among the examples \textcircled{1} to \textcircled{6} shown in (b) of FIG. 13, the current-conducting plating layers 150 of \textcircled{5} and \textcircled{6} may not be easy to manufacture in terms of the manufacturing process, and therefore, it is more preferable to provide the current-conducting plating layers 150 of \textcircled{1} to \textcircled{4} when considering an easier manufacturing process.

(b) of FIG. 13 shows a current-conducting plating layer 150 that can correspond to the B-B′ cross section, and the current-conducting plating layer 150 may be formed on any one part of the upper housing, the side wall housing, and the lower housing, and as an example, the current-lowering plating layer 150 is formed on one part of the lower housing.

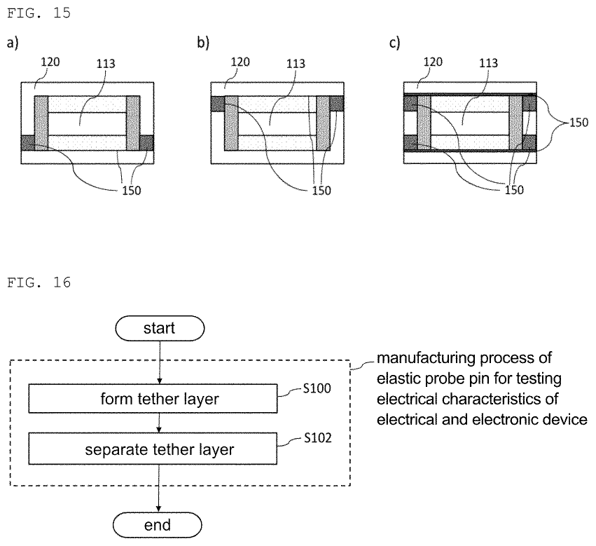

FIG. 14 is an example view showing other examples of the current-conducting plating layer shown in 13A.

As shown in FIG. 14, the current-conducting plating layer 150 may be formed on multiple parts of the upper housing, the side wall housing, and the lower housing, in addition to being formed on any one part of the upper housing, the side wall housing, and the lower housing. Furthermore, a plurality of current-conducting plating layers 150 may be formed on the upper housing, and the same applies to the side wall housing and the lower housing.

Due to this, it is possible to easily manufacture the probe 100 that meets the current transmission capability, including the required current amount and current transmission speed, depending on the performance and operating environment of the probe 100.

(a) to (c) of FIG. 15 are example views showing another example of the current-conducting plating layer provided in the housing of FIG. 12.

As shown in (a) to (c) of FIG. 15, the current-conducting plating layer 150 may be formed over a part of the side wall housing and a part of the upper housing, and likewise, the current-conducting plating layer 150 may be formed over a part of the side wall housing and a part of the lower housing.

Additionally, the thickness of the elastic portion 113 close to the contact portion 111 that comes into contact with the test object may be greater than the thickness of the elastic portion 113 close to the auxiliary contact portion 112 that comes into contact with the circuit board of the probe card.

In this case, the thickness of the elastic portion 113 means the width w of the elastic portion 113 or the height h of the elastic portion 113. As an example, in the case where the width w of the elastic portion 113 is thickened, the width w of the elastic portion 113 may be provided as 0.005 μm, and in contrast, the width w of the elastic portion 113 close to the auxiliary contact portion 112 may be provided as 0.004 μm.

In addition, the thickness of the elastic portion 113 corresponding to one part of the elastic portion 113 that is in contact with the contact portion 111 or the auxiliary contact portion 112 may be formed to be a predetermined thickness or greater than the thickness of the other part of the elastic portion 113 that is not in contact with the contact portion 111.

Due to this, in the case that a force is transmitted beyond the elastic restoring force of the elastic portion 113 due to the force applied to the contact portion 111 or the auxiliary contact portion 112, a structure may be provided that can prevent deformation of the contact portion 111 and the elastic portion 113, or deformation of the auxiliary contact portion 112 and the elastic portion 113 to some extent by hardware characteristics due to the thickness of the elastic portion 113 in contact with the contact portion 111 or the auxiliary contact portion 112.

FIG. 16 is a flow chart showing a manufacturing method of a vertical MEMS probe according to an embodiment of the present disclosure.

As shown in FIG. 16, a manufacturing method of a vertical MEMS probe 100 having a tethering structure includes a process of forming S100 a tether 140 that connects a contact portion 111 and a housing 120 or connects an elastic portion 113 and the housing 120 in a process of laminating a plurality of metal materials forming a pin 110 including the contact portion 111 that contacts at least one of the two ends of the pin 110 and the elastic portion 113 that withstands the contact load applied to the contact portion 111 by the elastic restoring force between the two ends and the housing 120 having a penetration portion a that exposes the contact portion 111 to the outside, and configured to cover the elastic portion 113, in a manufacturing process of the probe 100 having elasticity for examining electrical characteristics of an electrical or electronic device.

Thereafter, after removing a sacrificial layer, a process of separating S102 a first connection portion between the contact portion 111 or elastic portion 113 of the pin 110 and the tether 140, a second connection portion between the housing 120 and the tether 130, or the tether 130 is performed.

Detailed descriptions of steps S100 to S102 as described above and descriptions of additional possible steps follow FIGS. 1 to 16 and the descriptions of these drawings.

Although the embodiments of the present disclosure have been described with reference to the above and the attached drawings, a person skilled in the art will understand that the present disclosure n can be implemented in other specific forms without changing the technical idea or essential features thereof. Therefore, it should be understood that the embodiments described above are exemplary in all respects and not limiting.

### INDUSTRIAL APPLICABILITY

The present disclosure provides a vertical MEMS probe having a tethering structure capable of preventing bending of a probe pin that occurs when a sacrificial layer is removed, and a method for manufacturing the same. Accordingly, the present disclosure has sufficient possibility of being commercialized or sold, and is also clearly implementable in reality, and therefore, is an invention having industrial applicability.

What is claimed is:

1. A vertical MEMS probe having a tethering structure, the probe comprising:
a pin including a contact portion that contacts at least one of two ends thereof and an elastic portion that withstands a contact load applied to the contact portion by an elastic restoring force between the two ends;
a housing having a penetration portion that exposes the contact portion to outside, and configured to cover the elastic portion; and
a tether configured to connect the contact portion and the housing or the elastic portion and the housing,
wherein a first connection portion between the contact portion or the elastic portion and the housing, a second connection portion between the housing and the tether, or the tether can be separated.

2. The probe of claim 1, wherein the first connection portion, the second connection portion, or the tether is destroyed and separated by a mechanical external force during use of the vertical MEMS probe.

3. The probe of claim 2, wherein fracture toughness of the first connection portion, the second connection portion, or the tether is greater than a bending moment produced by residual stress of the contact portion and the elastic portion.

4. The probe of claim 2, wherein in a process where the first connection portion, the second connection portion, or the tether is destroyed by the mechanical external force, mechanical damage or plastic deformation of the contact portion or the elastic portion does not occur.

5. The probe of claim 2, wherein the tether includes a notch.

6. The probe of claim 1, wherein the first connection portion, the second connection portion, or the tether is separated using chemical etching.

7. The probe of claim 6, wherein the chemical etching includes galvanic corrosion.

8. The probe of claim 6, wherein a detether portion is included between the contact portion or the elastic portion and the tether, or between the housing and the tether,
wherein the detether portion is removed by the chemical etching.

9. The probe of claim 6, wherein the tether is divided into a first tether and a second tether, and a detether portion is further included between the first tether and the second tether,
wherein the detether portion is removed by the chemical etching.

10. The probe of claim 8, wherein when the chemical etching includes galvanic corrosion, a corrosion potential of the detether portion is lower than that of the contact portion and the elastic portion.

11. The probe of claim 1, wherein the housing is divided into an upper housing, a side wall housing, and a lower housing, and a current-conducting plating layer that acts as a current-conducting path is formed between plating layers forming any one of the upper housing, the side wall housing, and the lower housing or for a specific plating layer.

12. The probe of claim 11, wherein a short circuit with the current-conducting plating layer is created through an overall post-processing gold (Au) plating on the housing.

13. A manufacturing method of a vertical MEMS probe having a tethering structure, the method comprising:
forming a tether that connects a contact portion and a housing or connects an elastic portion and the housing in a process of laminating a plurality of metal materials forming a pin including the contact portion that contacts at least one of two ends of the pin and the elastic portion that withstands a contact load applied to the contact portion by an elastic restoring force between the two ends and the housing having a penetration portion that exposes the contact portion to outside, and configured to cover the elastic portion, in a manufacturing process of the probe having elasticity for examining electrical characteristics of an electrical or electronic device.

14. The method of claim 13, further comprising:
separating a first connection portion between the contact portion or the elastic portion and the housing, a second connection portion between the housing and the tether, or the tether.

15. The method of claim 14, wherein the first connection portion, the second connection portion, or the tether is destroyed and separated by a mechanical external force during use of the vertical MEMS probe.

16. The method of claim 14, further comprising one or more of the following steps:
(i) making fracture toughness of the first connection portion or the second connection portion to be greater than a bending moment produced by residual stress of the contact portion and the elastic portion;
(ii) providing a notch in the tether;
(iii) separating the first connection portion, the second connection portion, or the tether using chemical etching including galvanic corrosion;
(iv) providing a galvanic sacrificial layer to which the galvanic corrosion is applied with a metal material that is more electrochemically reactive than a metal material applied to the contact portion and the elastic portion;
(v) forming a detether portion between the contact portion or the elastic portion and the tether, or between the housing and the tether; and
(vi) dividing the tether into a first tether and a second tether, and further providing a detether portion between the first tether and the second tether.

17. The method of claim 16, when step (v) is elected, further comprising:
removing the detether portion using the chemical etching of the galvanic corrosion.

18. The method of claim 16, when step (vi) is elected, further comprising:
removing the detether portion using the chemical etching of the galvanic corrosion.

19. The method of claim 13, further comprising one or more of the following steps:
dividing the housing into an upper housing, a side wall housing, and a lower housing, and forming a current-conducting plating layer that acts as a current-conducting path between plating layers forming any one of the upper housing, the side wall housing, and the lower housing or for a specific plating layer; and
forming a thickness of the elastic portion close to the contact portion that comes into contact with a test object to be greater than that of the elastic portion close to an auxiliary contact portion that comes into contact with a circuit board of a probe card.

20. The method of claim 19, comprising:
creating a short circuit with the current-conducting plating layer through an overall post-processing gold (Au), silver (Ag), or platinum (Pt) plating on the housing.
